(19) United States
(12) Patent Application Publication
(10) Pub. No.: US 2025/0324790 A1
(43) Pub. Date: Oct. 16, 2025

(54) IMAGE SENSOR

(71) Applicant: Samsung Electronics Co., Ltd., Suwon-si (KR)

(72) Inventors: Taeksoo JEON, Suwon-si (KR); Kijoong YOON, Suwon-si (KR); Hajin LIM, Suwon-si (KR); Jaesung HUR, Suwon-si (KR)

(73) Assignee: Samsung Electronics Co., Ltd., Suwon-si (KR)

(21) Appl. No.: 18/904,198

(22) Filed: Oct. 2, 2024

(30) Foreign Application Priority Data
Apr. 12, 2024 (KR) 10-2024-0049560

(51) Int. Cl. H01L 27/146

(52) U.S. Cl. CPC H10F 39/8053; H10F 39/182; H10F 39/8063; H10F 39/811

(57) ABSTRACT

An image sensor includes photoelectric conversion devices in a substrate; a separation structure in the substrate and between the photoelectric conversion devices; an insulating structure on the substrate and the separation structure; color filters on the insulating structure; and a grid structure on the insulating structure and between the color filters. The grid structure includes spacer layers and a capping layer. The spacer layers have first surfaces opposing each other. The spacer layers define an air gap between the first surfaces that oppose each other. The capping layer covers second surfaces and upper surfaces of the spacer layers, and defines an upper limit of the air gap. The spacer layers have a first thickness, and the capping layer has a second thickness less than the first thickness.

### CROSS-REFERENCE TO RELATED APPLICATION(S)

This application claims benefit of priority to Korean Patent Application No. 10-2024-0049560 filed on Apr. 12, 2024 in the Korean Intellectual Property Office, the disclosure of which is incorporated herein by reference in its entirety.

### BACKGROUND

The inventive concepts relate to image sensors.

An image sensor may be a semiconductor-based sensor that receives light and generates an electrical signal. The image sensor may include a pixel array having a plurality of pixels, a logic circuit for driving the pixel array and generating an image. Each of the plurality of pixels may include a photodiode and a pixel circuit converting electric charges, generated by the photodiode, into an electrical signal. As the number of pixels included in an image sensor increases and a size of each of the pixels decreases, various methods have been proposed to effectively form devices disposed in respective pixels to provide a pixel circuit.

### SUMMARY

Some example embodiments of the inventive concepts provide an image sensor including a grid structure including an air gap.

Some example embodiments of the inventive concepts provide an image sensor including photoelectric conversion devices in a substrate; a separation structure in the substrate, the separation structure being between the photoelectric conversion devices; an insulating structure on the substrate and the separation structure; color filters on the insulating structure; and a grid structure on the insulating structure, the grid structure being between the color filters. The grid structure may include spacer layers having respective first surfaces opposing each other, the spacer layers defining an air gap between the first surfaces that oppose each other; and a capping layer covering upper surfaces of the spacer layers and second surfaces of the spacer layers other than the first surfaces, the capping layer defining an upper limit of the air gap. Each of the spacer layers may have a first thickness, and the capping layer may have a second thickness, less than the first thickness.

Some example embodiments of the inventive concepts further provide an image sensor including photoelectric conversion devices in a substrate; color filters on the substrate; and a grid structure on the substrate, the grid structure being between the color filters. The grid structure may have a pair of side surfaces extending vertically from the substrate, the pair of side surfaces facing each other; and an upper surface connecting upper portions of the pair of side surfaces, the pair of side surfaces and the upper surface defining an air gap below the upper surface. A thickness of the upper surface may be less than a thickness of each of side surfaces of the pair of side surfaces.

Some example embodiments of the inventive concepts still further provide an image sensor including a lower chip including a logic circuit; and an upper chip on the lower chip and bonded to the lower chip. The upper chip may include a plurality of filter groups including a plurality of color filters on a substrate; a separation structure in the substrate; an insulating structure on the substrate and the separation structure; a grid structure on the insulating structure, the grid structure being between the plurality of color filters; and a microlens on the grid structure. The grid structure may include a first grid structure and a second grid structure. The first grid structure may include spacer layers and a capping layer. The spacer layers may have a first thickness and may have first surfaces opposing each other, and the spacer layers define an air gap between the first surfaces that oppose each other. The capping layer many cover the air gap, upper surfaces of the spacer layers, and second surfaces of the spacer layers other than the first surfaces. The capping layer may have a second thickness less than the first thickness. Each of the plurality of filter groups may be surrounded by the first grid structure. The second grid structure may be between the plurality of color filters in each of the plurality of filter groups.

### BRIEF DESCRIPTION OF DRAWINGS

The above and other aspects, features, and advantages of the inventive concepts will be more clearly understood from the following detailed description, taken in conjunction with the accompanying drawings, in which:

FIG. 1 is a schematic block diagram of an image sensor according to some example embodiments of the inventive concepts;

FIG. 2 is a schematic circuit diagram of a pixel circuit according to some example embodiments;

FIG. 3 is a schematic diagram of an arrangement of pixels of the image sensor in FIG. 2;

FIG. 4 is an enlarged view of region “A” in FIG. 3;

FIG. 5 is a cross-sectional view of a portion of the pixels in FIG. 4;

FIG. 6 is an enlarged view of the image sensor illustrated in FIG. 5;

FIGS. 7, 8, 9 and 10 are enlarged views of a grid structure of an image sensor according to some example embodiments;

FIG. 11 is a schematic circuit diagram of a pixel circuit according to some example embodiments;

FIG. 12 is a schematic diagram of an arrangement of the pixels in FIG. 11;

FIG. 13 is a cross-sectional view of a portion of the pixels in FIG. 12;

FIGS. 14, 15 and 16 are plan views of an image sensor according to some example embodiments;

FIG. 17 is a chip configuration diagram of an image sensor according to some example embodiments;

FIG. 18 is a cross-sectional view of the image sensor in FIG. 17; and

FIGS. 19A, 19B, 19C, 19D, 19E, 19F and 19G are cross-sectional views of a method of manufacturing the image sensor in FIG. 5.

### DETAILED DESCRIPTION

Hereinafter, some example embodiments will be described in detail with reference to the accompanying drawings.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

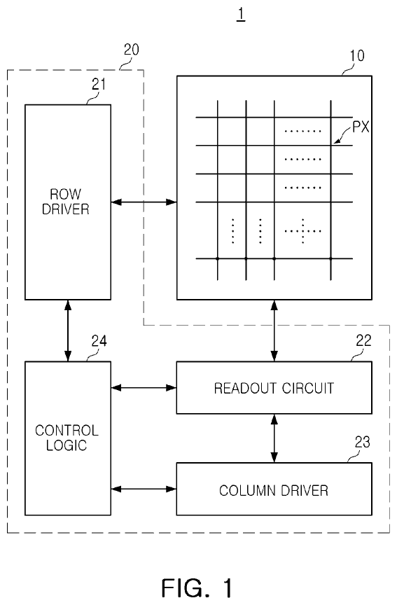

First, with reference to FIG. 1, an example of an image sensor according to some example embodiments will be described. FIG. 1 is a schematic block diagram of an image sensor according to some example embodiments.

Referring to FIG. 1, an image sensor 1 may include a pixel array 10 and a logic circuit 20. The pixel array 10 may include a plurality of pixels PX, disposed in the form of an array along a plurality of rows and a plurality of columns. Each of the plurality of pixels PX may include at least one photoelectric conversion device generating electric charges in response to light, and a pixel circuit generating a pixel signal corresponding to the electric charges generated by the photoelectric conversion device. The photoelectric conversion device may include a photodiode formed of a semiconductor material, and/or an organic photodiode formed of an organic material.

For example, the pixel circuit may include a floating diffusion region, a transfer transistor, a reset transistor, a driving transistor, and a selection transistor. A configuration of the pixels PX may vary according to some example embodiments. For example, each of the pixels PX may include an organic photodiode including an organic material, or may be implemented as a digital pixel. When the pixels PX are implemented as digital pixels, each of the pixels PX may include an analog-to-digital converter for outputting a digital pixel signal.

The logic circuit 20 may include circuits for controlling the pixel array 10. For example, the logic circuit 20 may include a row driver 21, a readout circuit 22, a column driver 23, and control logic (e.g., circuitry) 24. The row driver 21 may drive the pixel array 10 on a row line basis. For example, the row driver 21 may generate a transfer control signal for controlling a transfer transistor of a pixel circuit, a reset control signal for controlling a reset transistor, and a selection control signal for controlling a selection transistor, and may input the signals into the pixel array 10 on a row line basis.

The readout circuit 22 may include a correlated double sampler CDS, an analog-to-digital converter ADC, and the like. The correlated double samplers may be connected to the pixels PX through column lines. The correlated double samplers may read, from the pixels PX connected to a row line selected by a row line selection signal of the row driver 21, a pixel signal through the column lines. The analog-to-digital converter may convert the pixel signal, detected by the correlated double sampler, into a digital pixel signal and transmit the digital pixel signal to the column driver 23.

The column driver 23 may include a latch or buffer circuit capable of temporarily storing a digital pixel signal, or a buffer circuit and an amplifier circuit, and may process the digital pixel signal received from the readout circuit 22. The control logic 24 may control the row driver 21, the readout circuit 22, and the column driver 23. The control logic 24 may include a timing controller for controlling operation timings of the row driver 21, the readout circuit 22, and the column driver 23.

Among the pixels PX, pixels PX, disposed in the same position in a horizontal direction, may share the same column line. In some example embodiments, pixels PX, disposed in the same position in a vertical direction, may be simultaneously selected by the row driver 21, and may output a pixel signal through column lines. In some example embodiments, the readout circuit 22 may simultaneously obtain pixel signals from the pixels PX selected by the row driver 21 through the column lines. The pixel signal may include a reset voltage and a pixel voltage, and the pixel voltage may be a voltage in which electric charges, generated in response to light in each of the pixels PX, are reflected in the reset voltage.

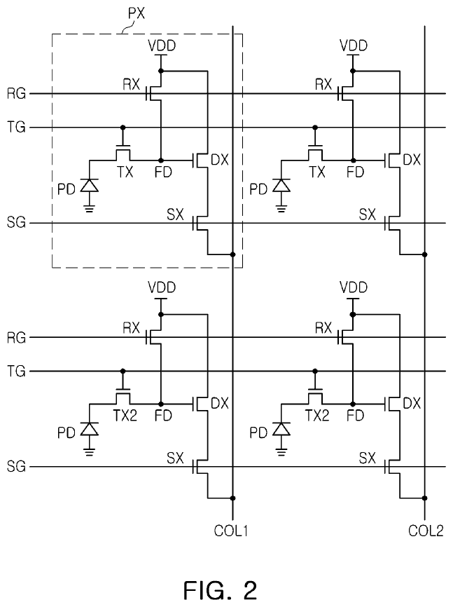

FIG. 2 illustrates an example of a pixel circuit of an image sensor according to some example embodiments.

Referring to FIG. 2, each of the plurality of pixels PX may include a photodiode PD and a pixel circuit, and the pixel circuit may include a transfer transistor TX, a reset transistor RX, a selection transistor SX, and a driving transistor DX.

The photodiode PD may generate and accumulate electric charges in response to externally incident light. The pixel circuit may further include a floating diffusion region FD in which the electric charges, generated by the photodiode PD, are accumulated.

The photodiode PD may be replaced with a phototransistor, a photogate, or a pinned photodiode according to some example embodiments. The photodiode PD may be referred to and described as a “photoelectric conversion device.” Accordingly, the photoelectric conversion device may be a photodiode, a phototransistor, a photogate, or a pinned photodiode.

The transfer transistor TX may move the electric charges, generated by the photodiode PD, to the floating diffusion region FD. The floating diffusion region FD may store the electric charges, generated by the photodiode PD. A voltage, output by the driving transistor DX, may vary depending on an quantity of electric charges accumulated in the floating diffusion region FD.

The reset transistor RX may reset a voltage of the floating diffusion region FD by removing the electric charges accumulated in the floating diffusion region FD. A drain electrode of the reset transistor RX may be connected to the floating diffusion region FD, and a source electrode of the reset transistor RX may be connected to a power supply voltage VDD. When the reset transistor RX is turned on, responsive to a reset control signal RG, the power supply voltage VDD, connected to the source electrode of the reset transistor RX, may be applied to the floating diffusion region FD, and the electric charges accumulated in the floating diffusion region FD may be removed.

The driving transistor DX may operate as a source follower buffer amplifier. The driving transistor DX may amplify a voltage change in the floating diffusion region FD, and may output the amplified voltage change to one of column lines COL1 and COL2. The selection transistor SX, responsive to a selection control signal SG, may select pixels PX to be read on a row basis. When the selection transistor SX is turned on, a voltage of the driving transistor DX may be output to one of the column lines COL1 and COL2. When the selection transistor SX is turned on, a reset voltage or a pixel voltage may be output through the column lines COL1 and COL2.

In some example embodiments as illustrated in FIG. 2, each of the plurality of pixels PX may include the reset transistor RX, the selection transistor SX, and the driving transistor DX, and the photodiode PD and the transfer transistor TX, but some example embodiments of the inventive concepts are not limited thereto.

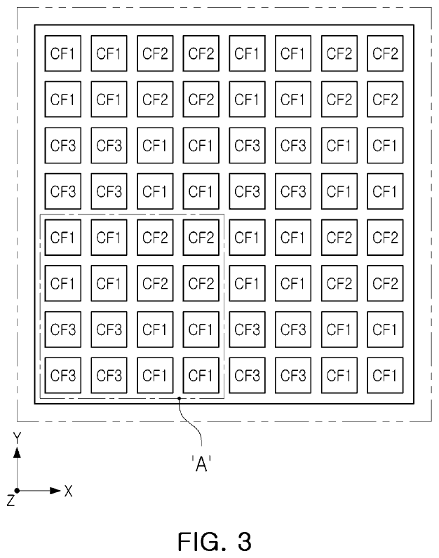

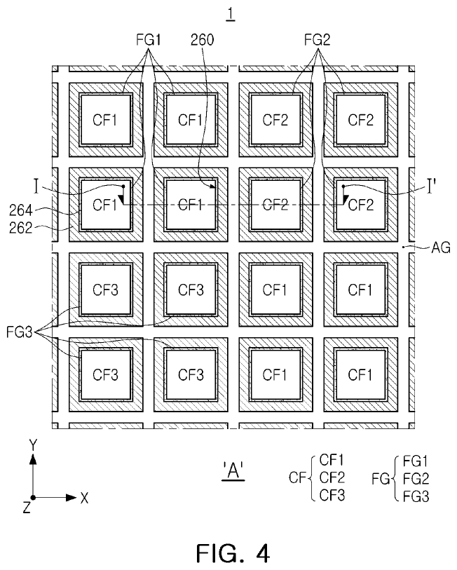

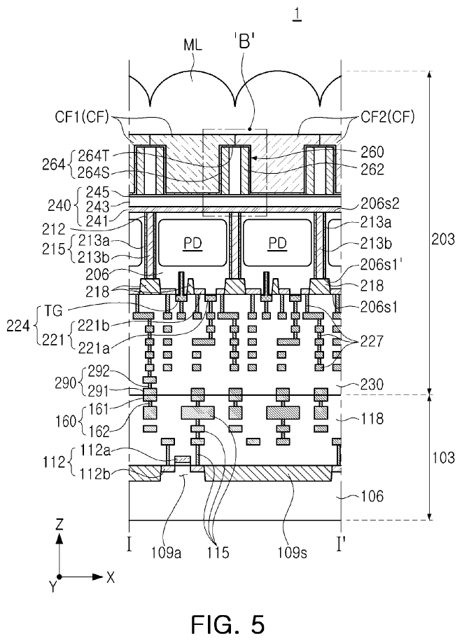

With reference to FIGS. 3 to 5, an example of an image sensor structure according to some example embodiments will be described. FIGS. 3 to 5 are schematic diagrams of an image sensor according to some example embodiments. FIG. 3 is a schematic plan view of an image sensor according to some example embodiments, FIG. 4 is an enlarged view of the image sensor illustrated in FIG. 3, and FIG. 5 is a vertical cross-sectional view of the image sensor illustrated in FIG. 4, taken along line I-I′.

Referring to FIGS. 3 to 5, an image sensor 1 according to some example embodiments may have a multilayer chip structure including at least two chips. For example, the image sensor 1 may include a first chip structure 103 and a second chip structure 203 on the first chip structure 103. The first chip structure 103 may be a logic chip, and the second chip structure 203 may be an image sensor chip. In some example embodiments, the first chip structure 103 may be a multilayer chip structure including a logic chip and a memory chip.

The first chip structure 103 of the image sensor 1 may include a first substrate 106, an isolation film 109s, defining an active region 109a, on the first substrate 106, a first circuit device 112 and a first interconnection line structure 115 on the first substrate 106, a first insulating structure 118, covering the first circuit device 112 and the first interconnection line structure 115, on the first substrate 106, and a first bonding structure 160.

The first substrate 106 may be a semiconductor substrate. For example, the first substrate 106 may be a substrate formed of a semiconductor material, for example, a single crystal silicon substrate. The first circuit device 112 may include an device such as a transistor including a gate 112a and a source/drain 112b. The first bonding structure 160 may be connected to the first interconnection line structure 115, on the first interconnection line structure 115. The first bonding structure 160 may include a metal material such as copper (Cu) or the like. The first bonding structure 160 may include a first bonding pad 161 and a first bonding via 162 connected to the first bonding pad 161. The first bonding pad 161 may function as a bonding layer with the second chip structure 203, and may provide an electrical connection path with the second chip structure 203. The first insulating structure 118 may cover the first circuit devices 112 and the first interconnection line structure 115, and may cover a portion of the first bonding structure 160.

The second chip structure 203 may include a second substrate 206 having a first surface 206s1 and a second surface 206s2 opposing each other, an isolation film 218 disposed on the first surface 206s1 of the second substrate 206, the isolation film 218 defining an active region, a second circuit device 224 and a second interconnection line structure 227 disposed between the first surface 206s1 of the second substrate 206 and the first chip structure 103, and a second insulating structure 230, covering the second circuit device 224 and the second interconnection line structure 227, between the first surface 206s1 of the second substrate 206 and the first chip structure 103, and a second bonding structure 290. The first surface 206s1 of the second substrate 206 may oppose the first chip structure 103. The isolation film 218 may be formed of an insulating material such as silicon oxide. The second circuit device 224 and the second interconnection line structure 227, disposed below the first surface 206s1 of the second substrate 206, may be included in a circuit interconnection line structure. Accordingly, a circuit interconnection line structure may be disposed below the first surface 206s1 of the second substrate 206.

In some example embodiments, a bottom surface of the isolation film 218 may be referred to as a second surface 206s1′ of the substrate 206.

The second substrate 206 may be a semiconductor substrate. For example, the second substrate 206 may be a substrate formed of a semiconductor material, for example, a single crystal silicon substrate.

The photoelectric conversion devices PD may generate and accumulate electric charges corresponding to incident light. For example, the photoelectric conversion devices PD may include a photodiode, a phototransistor, a photogate, a pinned photodiode PPD, or combinations thereof. Each of the photoelectric conversion devices PD may be a photodiode that may be formed in the second substrate 206.

The second chip structure 203 may further include a separation structure 215. The separation structure 215 may be disposed to surround each of the photoelectric conversion devices PD. The separation structure 215 may vertically pass through at least a portion of the second substrate 206. For example, the separation structure 215 may vertically pass through the second substrate 206. The separation structure 215 may be disposed in a separation trench 212 vertically passing through the second substrate 206. For example, the second substrate 206 may define separation trenches 212 vertically passing therethrough. The isolation structure 215 may be connected to the isolation film 218. Accordingly, the isolation structure 215 may pass through the second substrate 206 between the isolation film 218 and the second surface 206s2 of the second substrate 206. The separation structure 215 may have a substantially vertical side surface.

The separation structure 215 may include a separation pattern 213b and a separation insulating layer 213a, covering a side surface of the separation pattern 213b. For example, the separation insulating layer 213a may include silicon oxide, and the separation pattern 213b may include polysilicon. The separation pattern 213b may also be referred to as a silicon pattern or poly-silicon pattern. The separation insulating layer 213a may be formed of a single material layer.

The separation pattern 213b may be formed of a material capable of applying a voltage to the separation pattern 213b so as to limit and/or minimize and/or prevent interference or influence between the photoelectric conversion devices PD. For example, the separation pattern 213b may include a conductive material, for example, doped polysilicon. In some example embodiments, the separation pattern 213b may be formed of doped polysilicon having an N-type conductivity type. In some example embodiments, the separation pattern 213b may be formed of doped polysilicon having a P-type conductivity type.

The second circuit device 224 may include a transfer gate TG and active devices 221. The active devices 221 may be transistors including a gate 221a and a source/drain 221b. The transfer gate TG may transfer electric charges from an adjacent photoelectric conversion device PD to an adjacent floating diffusion region. The active devices 221 may be various transistors of the pixel circuits described with reference to FIG. 2, for example, a driving transistor, a reset transistor, and a selection transistor.

The transfer gate TG may be a vertical transfer gate including a portion extending from the first surface 206s1 of the second substrate 206 to the inside of the second substrate 206.

The second interconnection line structure 227 may include multilayer interconnection lines, positioned on different height levels, and vias, electrically connecting the multilayer interconnection lines to each other and electrically connecting the multilayer interconnection lines to the second circuit device 224.

The first insulating structure 118 and the second insulating structure 230 may be bonded to each other while being in contact with each other. Each of the first and second insulating structures 118 and 230 may be formed of multiple layers including different types of insulating layers. For example, the second insulating structure 230 may be formed of multiple layers including at least two types of layers, among a silicon oxide layer, a low-K dielectric layer, and a silicon nitride layer. The second bonding structure 290 may be connected to the second interconnection line structure 227, on the second interconnection line structure 227. The second bonding structure 290 may include a metal material such as copper (Cu) or the like. The second bonding structure 290 may include a second bonding pad 291 and a second bonding via 292 connected to the second bonding pad 291. The second bonding pad 291 may function as a bonding layer with the first chip structure 103, and may provide an electrical connection path with the first chip structure 103. That is, the second bonding pad 291 may be in contact with the first bonding pad 161 of the first bonding structure 160 of the first chip structure 103 to form a Cu—Cu bonding structure, and may implement hybrid bonding, together with bonding of surrounding insulating structures 118 and 230.

The second chip structure 203 may further include an insulating structure 240, disposed on the second surface 206s2 of the second substrate 206. The insulating structure 240 may cover the separation structure 215.

The insulating structure 240 may include an anti-reflection layer 241 and a substrate insulating layer 243. The anti-reflection layer 241 may limit and/or prevent reflection of light that may occur due to a sudden change in refractive index of the second surface 206s2 of the second substrate 206, which may be formed of silicon. The anti-reflection layer 241 may adjust a refractive index to allow incident light to pass through the photoelectric conversion devices PD with high transmittance. The anti-reflection layer 241 may include at least one of metal oxide, for example, aluminum oxide and hafnium oxide.

The substrate insulating layer 243 may include a material capable of adjusting a peak of transmittance by adjusting a thickness. For example, the substrate insulating layer 243 may include an oxide such as silicon oxide or the like. The substrate insulating layer 243 may have a thickness, greater than that of a lower anti-reflection layer 241, but the inventive concepts are not limited thereto. The substrate insulating layer 243 may be formed of a single layer or a plurality of layers. The insulating structure 240 may have transparency at visible wavelengths, and may include a material having a negative charge to limit and/or prevent a charge caused by a dangling bond of the second side 206s2 of the substrate 206.

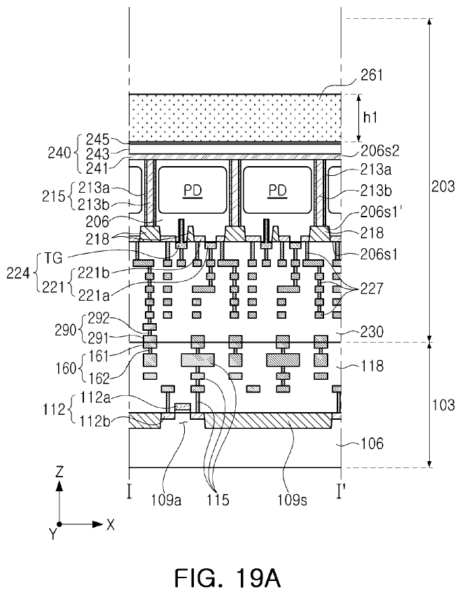

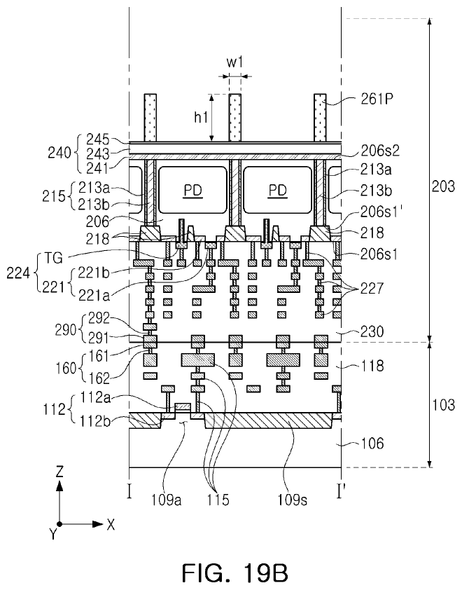

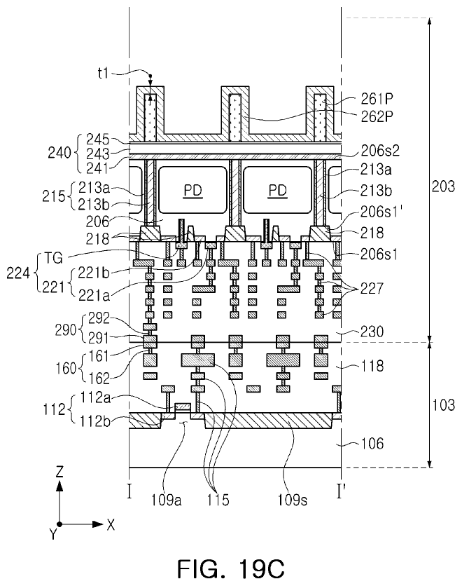

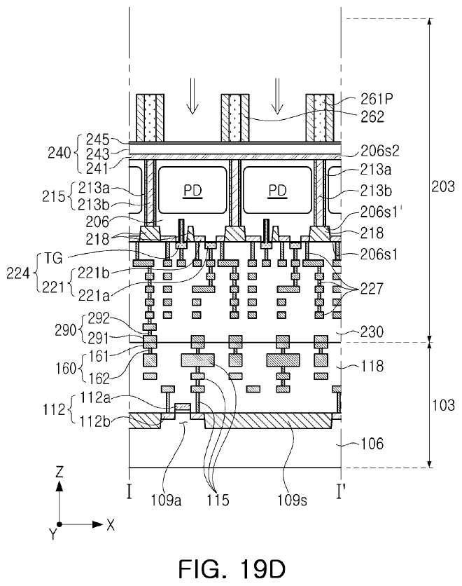

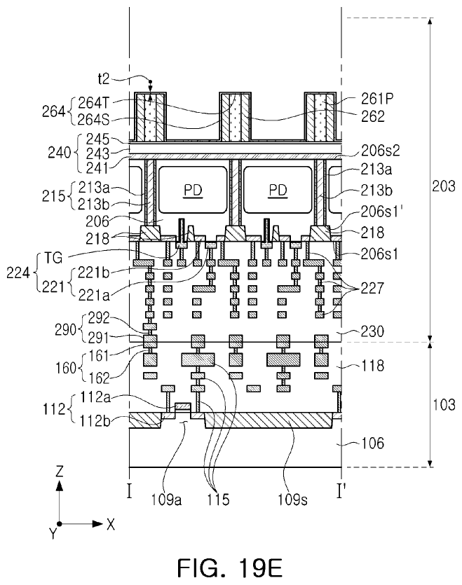

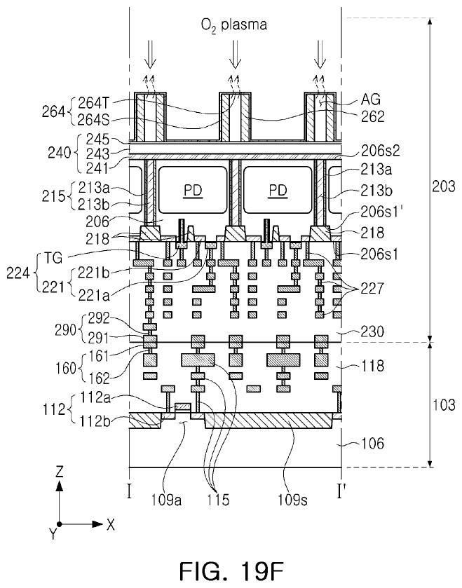

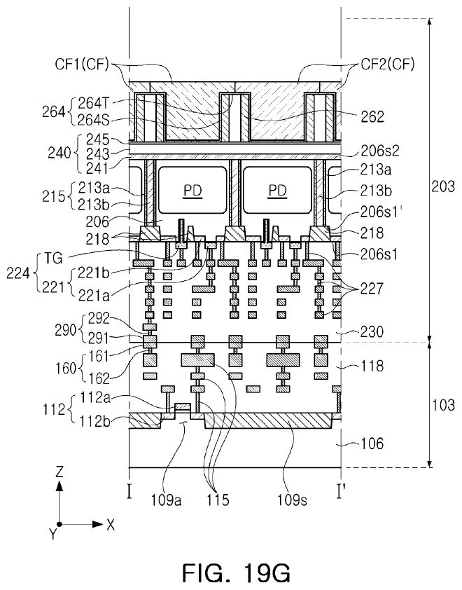

The insulating structure 240 may further include an etch stop layer 245, on the substrate insulating layer 243 on the second surface 206s2 of the second substrate 206. The etch stop layer 245 may function as an etching stopper when the sacrificial layer 261 (e.g., see FIG. 19A) for forming the grid structure 260 is patterned. When the sacrificial layer 261 for forming the grid structure 260 and the lower substrate insulating layer 243 have etching selectivity for a specific etchant, the etch stop layer 245 may be omitted.

The second chip structure 203 may include color filters CF. For example, the color filters CF may include color filters, filtering different colors. For example, the color filters CF may include at least one of green color filters, blue color filters, red color filters, white color filters, and yellow color filters.

The color filters CF may be disposed on the insulating structure 240. The color filters CF may vertically overlap the photoelectric conversion devices PD, respectively corresponding thereto. The color filters CF may allow light having a specific wavelength to pass therethrough and reach the photoelectric conversion devices PD. For example, the color filters CF may be formed of a material obtained by mixing a resin with a pigment including a metal or metal oxide.

In some example embodiments, the plurality of color filters CF may include a plurality of first color filters CF1, a plurality of second color filters CF2, and a plurality of third color filters CF3. In some example embodiments, the first color filters CF1, the second color filters CF2, and the third color filters CF3 may be respectively disposed in a 2×2 array. According to some example embodiments, the plurality of first color filters CF1, the plurality of second color filters CF2, and the plurality of third color filters CF3 may be respectively disposed in a 1×1 array, a 3×3 array, or a 4×4 array. In some example embodiments, the plurality of color filters CF may have a rectangular shape, in plan view.

Among the plurality of first color filters CF1, first color filters CF1, disposed to be adjacent to each other, may be included in first filter groups FG1. Among the plurality of second color filters CF2, second color filters CF2, disposed to be adjacent to each other, may be included in second filter groups FG2. Among the plurality of third color filters CF3, third color filters CF3, disposed to be adjacent to each other, may be included in third filter groups FG3. For example, the first filter group FG1, the second filter group FG2, and the third filter group FG3 may include four first color filters CF1, four second color filters CF2, and four third color filters CF3, respectively. Different filter groups FG may be configured to filter different colors. For example, the color filters CF1 and CF2, illustrated in FIG. 5, may be different types of color filters.

The second chip structure 203 may further include a grid structure 260. The grid structure 260 may be disposed on the insulating structure 240. In some example embodiments, the grid structure 260 may vertically overlap the separation structure 215. In some example embodiments, the grid structure 260 may have a width different from that of the separation structure 215. For example, the width of the grid structure 260 may be greater than the width of the separation structure 215. The grid structure 260 may extend in a horizontal direction, between the plurality of color filters CF. For example, the grid structure 260 may separate color filters CF from each other.

The grid structure 260 may extend in an X-direction and a Y-direction, between the color filters CF. The grid structure 260 may also be disposed between the first color filter CF1 of the first filter group FG1 and the second color filter CF2 of the second filter group FG2, adjacent thereto, and may extend in the X-direction and the Y-direction, between the same color filter CF in each filter group. The first color filters CF1, disposed in the first filter group FG1, may be spaced apart from each other by the grid structure 260. In some example embodiments, the grid structure 260 may include row grids extending in the X-direction between the color filters CF, and column grids extending in the Y-direction between the color filters CF. The row grids and the column grids may intersect each other and form integrally. In some example embodiments, the plurality of color filters CF may be surrounded by the grid structure 260.

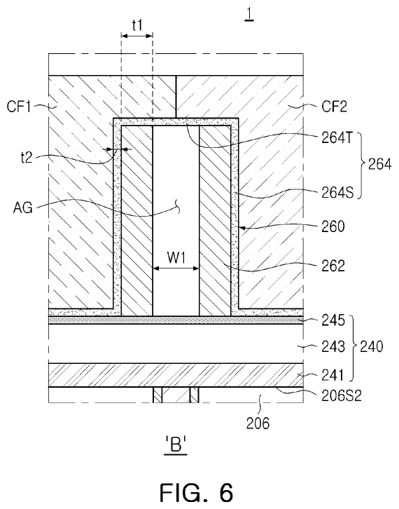

FIG. 6 is an enlarged view of region “B” of the image sensor illustrated in FIG. 5.

Referring further to FIG. 6, the grid structure 260 may include a spacer layer 262 and a capping layer 264. Each grid structure 260 may include two spacer layers 262 opposing each other with an air gap AG therebetween, and the two spacer layers 262 may be spaced from each other by a separation distance corresponding to a width W1 of the air gap AG, and extend to be parallel to each other. The two spacer layers 262 may be spaced apart from each other in a direction, intersecting a direction in which the grid structure 260 extends. Each spacer layer 262 may have an internal surface (e.g., a first surface) and an external surface (e.g., a second surface). The two adjacent spacer layers 262 may be disposed such that internal surfaces oppose each other. The spacer layers 262 may extend in the X-direction and the Y-direction along the grid structure 260. The spacer layers 262 may include at least one of silicon oxide, silicon nitride, and silicon carbonitride, and may be disposed to have a first thickness t1.

The capping layer 264 may cover side and upper surfaces of the spacer layers 262. For example, the spacer layers 262 may be disposed in the capping layer 264, and the capping layer 264 may be in contact with external surfaces of the spacer layers 262. The capping layer 264 may have an arch shape, and may surround the spacer layers 262. An upper surface of the capping layer 264 may be positioned on a level, higher than that of an upper surface of the spacer layer 262. The capping layer 264 may be disposed to cover an upper portion of the insulating structure 240, that is, an upper surface of the etch stop layer 245.

For example, the capping layer 264 may include a vertical portion 264S and a horizontal portion 264T. The vertical portion 264S may refer to a portion of the capping layer 264, lower than the upper surface of the spacer layer 262, and the horizontal portion 264T may refer to a portion of the capping layer 264, higher than the upper surface of the spacer layer 262. The vertical portion 264S may be disposed on the outside of the spacer layer 262 with respect to a central portion of the grid structure 260, and may cover an external surface of the spacer layer 262. The horizontal portion 264T may be disposed on the vertical portion 264S, and may cover the spacer layer 262 and an upper portion of the air gap AG. The capping layer 264 may include at least one of silicon oxide and silicon nitride, and may be disposed to have a second thickness t2, less than the first thickness t1. The first thickness t1 may be 4 to 7 times the second thickness t2, preferably 5 to 6 times the second thickness t2. The first thickness t1 may be 150 Å to 350 Å, preferably 300 Å to 320 Å, and the second thickness t2 may be 20 Å to 60 Å. For example, the first thickness t1 may be 300 Å, the second thickness t2 may be 50 Å or less. It may be described that the second thickness t2 satisfies ⅙ or less of the first thickness t1, but the inventive concepts are not limited thereto. However, the capping layer 264, covering the upper portion of the air gap AG, may be formed sufficiently thin to have the second thickness t2, and thus plasma may pass through the horizontal portion 264T, such that the sacrificial layer 261 (e.g., see FIGS. 19E and 19F) may vaporize. The capping layer 264 and the spacer layer 262 may include the same material, for example, silicon oxide or silicon nitride, but the inventive concepts are not limited thereto.

The capping layer 264 may be conformally disposed along the grid structure 260 from above the etch stop layer 245, such that the grid structure 260 may include the spacer layer 262 and the air gap AG therein. For example, the air gap AG may be formed between the spacer layers 262, and the air gap AG may be defined by the spacer layers 262 and the capping layer 264. For example, an upper limit of the air gap AG may be defined by the capping layer 264, and a lower limit of the air gap AG may be defined by the etch stop layer 245. A lateral limit of the air gap AG may be defined by the spacer layers 262. The air gap AG may be sealed in the grid structure 260. For example, the air gap AG may be sealed or formed as bounded by the spacer layers 262 and the capping layer 264. The grid structure 260 may have an air gap AG having a refractive index of 1 therein, thereby limiting and/or preventing and/or reducing an optical crosstalk phenomenon of the image sensor 1. The grid structure 260 may have an internal space for insulating materials to form the air gap AG, and a combined thickness of the spacer layer 262 and the capping layer 264 may be significantly greater than a thickness of the capping layer 264. Accordingly, a structurally stable grid structure 260 may be formed.

On a plane, each of a plurality of spacer layers 262 of the grid structure 260 may surround one corresponding color filter CF, and may have a rectangular shape. A plurality of capping layers 264 may respectively surround corresponding color filters CF, and may have a rectangular shape.

In some example embodiments, the grid structure 260 may be disposed between the color filters CF. A thickness of each of the color filters CF may be greater than a thickness of the grid structure 260. A portion of the color filters CF may cover the grid structure 260, on the insulating structure 240. For example, the color filters CF may cover side and upper surfaces of the grid structure 260, on the insulating structure 240.

In some example embodiments, the grid structures 260, including the air gap AG, may be disposed between the filter groups FG, and thus may be disposed between color filters CF, filtering different colors. Accordingly, an optical crosstalk phenomenon occurring between different color filters CF may be limited and/or prevented and/or reduced. The grid structure 260 may be disposed between the color filters CF, filtering different colors, thereby improving light sensitivity of the image sensor 1. The spacer layer 262 may be formed to be significantly thicker than the capping layer 264, and thus may function as a vertical support maintaining the air gap AG and may limit and/or prevent the air gap AG from collapsing.

The second chip structure 203 may further include microlenses ML on the color filters CF. The microlenses ML may vertically overlap the color filters CF, respectively. In some example embodiments, each of the microlenses ML may vertically overlap one color filter CF. Alternatively, the microlenses ML may vertically overlap a plurality of filter groups FG, respectively. For example, one microlens, among the microlenses ML, may vertically overlap one group, among the plurality of filter groups FG. Accordingly, the microlenses ML may vertically overlap the plurality of color filters CF, respectively. For example, one microlens ML, among the microlenses ML, may vertically overlap four color filters CF, among the plurality of color filters CF.

Each of the microlenses ML may have a convex shape in a direction away from the first chip structure 103. The microlenses ML may converge incident light into the photoelectric conversion devices PD. The microlenses ML may be formed of a transparent photoresist material or a transparent thermosetting resin material. For example, the microlenses ML may be formed of a TMR series resin (produced by Tokyo Ohka Kogo, Co., Ltd.) or an MFR series resin (produced by Japan Synthetic Rubber Corporation), but a material of the microlenses ML is limited to the above-described materials.

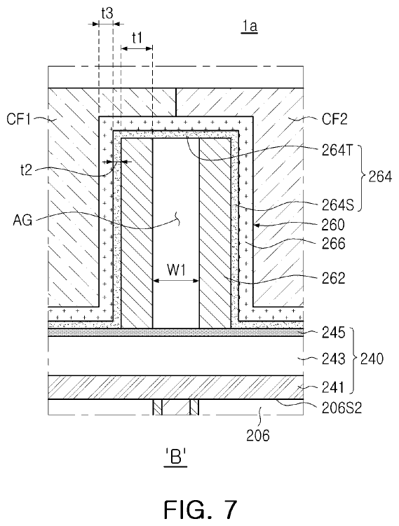

Hereinafter, image sensors according to some example embodiments will be described with reference to FIGS. 7 to 10.

Referring to FIG. 7, an image sensor 1a according to some example embodiments may be the same as that in FIG. 6, except that a passivation layer 266 is further included.

In the image sensor 1a, a grid-shaped grid structure 260 may be disposed on an insulating structure 240. As illustrated in FIG. 6, the grid structure 260 may include a spacer layer 262, a capping layer 264 covering the spacer layer 262, and may further include a passivation layer 266 covering the capping layer 264.

When the capping layer 264 is conformally disposed to cover an etch stop layer 245 of the insulating structure 240, the passivation layer 266 may be conformally disposed along the capping layer 264. The passivation layer 266 may be disposed to have a third thickness t3, and the third thickness t3 may be less than a first thickness t1, and may be greater than a second thickness t2. Accordingly, the passivation layer 266, having a thickness greater than that of the capping layer 264, may be disposed on the capping layer 264, and thus may be more structurally stabilized. The passivation layer 266 may include at least one of silicon oxide, aluminum oxide, and hafnium oxide.

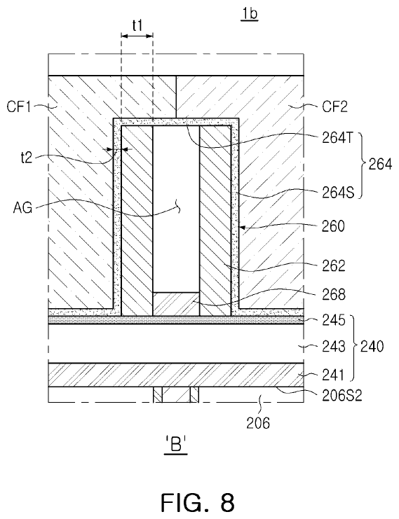

Referring to FIG. 8, an image sensor 1b according to some example embodiments may be the same as that in FIG. 6, except that a barrier layer 268 is further included.

In some example embodiments, the barrier layer 268 may be disposed between spacer layers 262. The barrier layer 268 may include a conductive material. For example, the barrier layer 268 may be formed of a conductive material including at least one of a metal or metal nitride. For example, the barrier layer 268 may include at least one of Ti, Ta, TiN, TaN, or W. The barrier layer 268, formed of a conductive material, may serve as a charge path for removing a charge, when a second surface 206s2 of a substrate 206 is charged. A lower surface of the barrier layer 268 may be coplanar with a lower surface of the spacer layer 262 and a lower surface of the capping layer 264, and may be in contact with an upper surface of an insulating structure 240.

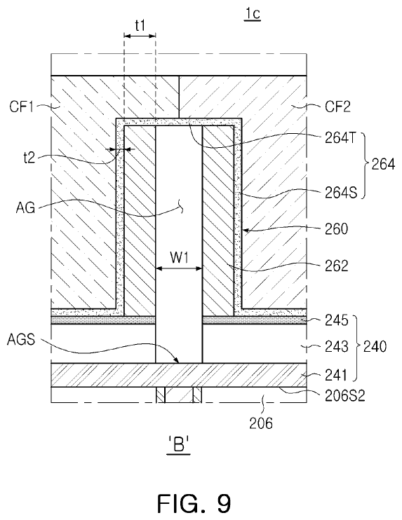

Referring to FIG. 9, an image sensor 1c according to some example embodiments may be the same as that in FIG. 6, except that an air gap AG is recessed into an insulating structure 240.

In some example embodiments, the air gap AG may have a first width W1, and may be formed between spacer layers 262. The air gap AG may have both surfaces defined by the internal surfaces of the spacer layers 262, may have an upper end defined by the capping layer 264, and may have a lower end AGS positioned on a level, lower than that of an upper surface of the insulating structure 240. For example, the lower end AGS of the air gap AG may be defined by an upper surface of an anti-reflection layer 241 of the insulating structure 240.

As described, the air gap AG may have a uniform width W1, and may have a lower end AGS disposed on a level, lower than that of the upper surface of the insulating structure 240 and higher than that of a second surface 206S2 of a second substrate 206, such that the air gap AG may have a more increased length. As the length of the air gap AG gradually increases, a distance between color filters CF, with the air gap AG interposed therebetween, may increase, thereby significantly reducing crosstalk. In some example embodiments, the lower end AGS of the air gap AG may be disposed to be higher than the second surface 206S2 of the second substrate 206 and to be spaced apart from a separation structure 215.

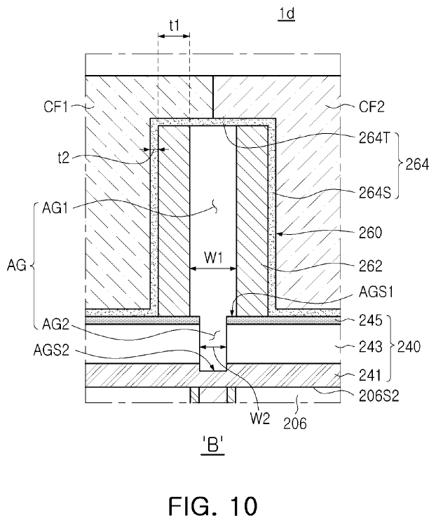

Referring to FIG. 10, an image sensor 1d according to some example embodiments may be the same as that in FIG. 9, except that a lower end of an air gap AG is formed to have a step.

In some example embodiments, the air gap AG may include a first region AG1 defined by spacer layers 262 and a capping layer 264 from an upper surface of an insulating structure 240, and a second region AG2 recessed into the insulating structure 240. The first region AG1 may have a first width W1, and may be formed between the spacer layers 262. The first region AG1 of the air gap AG may have both side surfaces defined by internal surfaces of the spacer layers 262, may have an upper end defined by the capping layer 264, and may have a lower end connected to the second region AG2. The second region AG2 may be formed to have a second width W2, less than the first width W1, such that a connection portion between the first region AG1 and the second region AG2 may have a step. Accordingly, the air gap AG may include a first lower end AGS1 in contact with the upper surface of the insulating structure 240, the first lower end AGS1 having the second width W2 changed from the first width W1, and a second lower end AGS2 that is a lower end of the second region AG2. The second region AG2 may include the second lower end AGS2 recessing (e.g., recessed in) the insulating structure 240 in a Z-direction from the first lower end AGS1, the second lower end AGS2 positioned on a level, higher than that of the second surface 206S2 of the second substrate 206. For example, the second lower end AGS2 may be disposed on a level, higher than that of the second substrate 206 and lower than that of an upper surface of an anti-reflection layer 241, and may be disposed to recess a portion of the anti-reflection layer 241. As described, when the air gap AG is expanded to be recessed into the insulating structure 240, a process of recessing the insulating structure 240 and a process of forming, by a sacrificial layer 261, the first region AG1 between the spacer layer 262 may be performed separately. Accordingly, the first region AG1 may be formed to cover the second region AG2 to facilitate alignment, to form the air gap AG by different processes. In some example embodiments, the first region AG1 and the second region AG2 may be aligned to have the same axis.

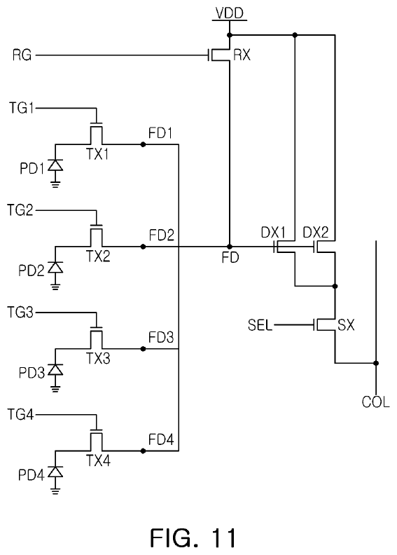

Hereinafter, some example embodiments of the present disclosure will be described with reference to FIGS. 11 to 13.

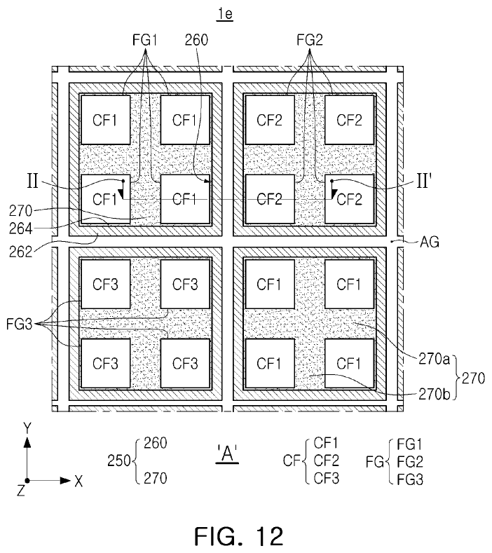

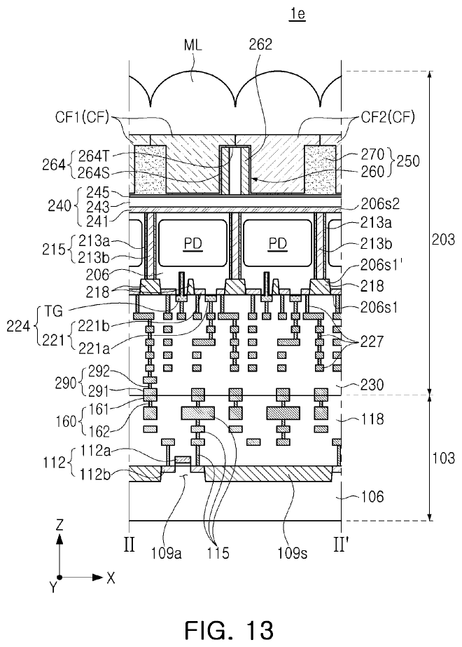

FIG. 11 is a schematic circuit diagram of a pixel circuit according to some example embodiments of the inventive concepts. FIG. 12 is a schematic diagram of an arrangement of the pixels in FIG. 11. FIG. 13 is a cross-sectional view of a portion of the pixels in FIG. 12.

Referring to FIG. 11, unlike FIG. 2, two or more pixels, adjacent to each other, may share at least a portion of transistors included in a pixel circuit. For example, four pixels, adjacent to each other, may share one floating diffusion region FD, a reset transistor RX, first and second driving transistors DX1 and DX2, and a selection transistor SX.

In some example embodiments, a first photodiode PD1 and a first transfer transistor TX1 of a first pixel may be connected to the floating diffusion region FD. Similarly, second to fourth photodiodes PD2 to PD4 of second to fourth pixels may be connected to the floating diffusion region FD through second to fourth transfer transistors TX2 to TX4.

In some example embodiments, the floating diffusion regions FD, respectively included in the pixels, may be connected to each other using an interconnection line pattern or the like, such that the first to fourth transfer transistors TX1 to TX4 may be connected to one floating diffusion region FD in common.

In some example embodiments, the floating diffusion regions FD1 to FD4, respectively included in the pixels, may be formed as one floating diffusion region FD in a substrate that may be formed of a semiconductor material.

The pixel circuit may include the reset transistor RX, the first and second driving transistors DX1 and DX2, and the selection transistor SX. The reset transistor RX may be controlled by a reset control signal RG, and the selection transistor SX may be controlled by a selection control signal SEL. For example, each of the four pixels may further include one transistor in addition to the transfer transistor TX. Among four transistors included in the four pixels, two transistors may be connected to each other in parallel and provided as the first and second driving transistors DX1 and DX2, and one of the remaining two transistors may be provided as the selection transistor SX, and the other one may be provided as the reset transistor RX.

The pixel circuit, described with reference to FIG. 11, is merely an example and is not necessarily limited to such a form. For example, among four transistors, one transistor may be assigned as a driving transistor, and one transistor may be assigned as a selection transistor. The remaining two transistors may be connected to each other in series and assigned as first and second reset transistors, thereby implementing an image sensor capable of adjusting a conversion gain of a pixel. Alternatively, the pixel circuit may vary, depending on the number of transistors included in each of the pixels.

An example arrangement of color filters CF for the pixel circuit in FIG. 11 may be the same as that in FIG. 12. Referring to FIG. 12, color filters CF having the same color may be disposed in a 2×2 array, and may be included in one filter group FG. That is, four photodiodes PD in FIG. 11 may be disposed in the 2×2 array, and the one filter group FG may be disposed to align with the photodiodes PD. In some example embodiments, transistors may be shared according to the pixel circuit in FIG. 11.

In FIG. 12, when the one filter group FG is defined on a plane, the grid structure 260 in FIGS. 4 to 6 may be disposed as a first grid structure 260, and a second grid structure 270, different from the first grid structure 260, may be disposed between color filters CF in each filter group FG.

Accordingly, a grid structure 250 of an image sensor 1e in FIG. 12 may include a first grid structure 260 and a second grid structure 270. A configuration of the first grid structure 260 may be the same as described above, and may have a rectangular shape to partition the one filter group FG.

The second grid structure 270 may include a material the same as that of the capping layer 264. For example, the second grid structure 270 may include silicon oxide. The second grid structure 270 may not include components, corresponding to the spacer layer 262 of the first grid structure 260 and the air gap AG. In some example embodiments, the second grid structure 270 may have a horizontal width, equal to a horizontal width of the first grid structure 260, but the inventive concepts are not limited thereto. In some example embodiments, the horizontal width of the first grid structure 260 may be greater than the horizontal width of the second grid structure 270.

In some example embodiments, the capping layer 264 of the first grid structure 260 may be connected to the second grid structure 270, and may be formed integrally with the second grid structure 270. For example, in plan view, in the same filter group FG, the capping layer 264 of the first grid structure 260 may be connected to the second grid structure 270, and the capping layer 264 and the second grid structure 270 may be materially continuous.

Accordingly, different grid structures 260 and 270 may be included in one image sensor 1e, such that the first grid structure 260, including the air gap AG, may be disposed between different filter groups FG. The second grid structure 270, including only the capping layer 264 without the air gap AG, may be disposed between color filters CF having the same color, with the second grid structure 270 in a filter group FG including second grid structure portions 270a extending along the X-direction between color filters CF having the same color, and second grid structure portions 270b extending along the Z-direction between color filters CF having the same color. As described, a configuration of the grid structure 260 may vary according to a color arrangement of the color filter CF, thereby ensuring both structural stability and crosstalk prevention effects.

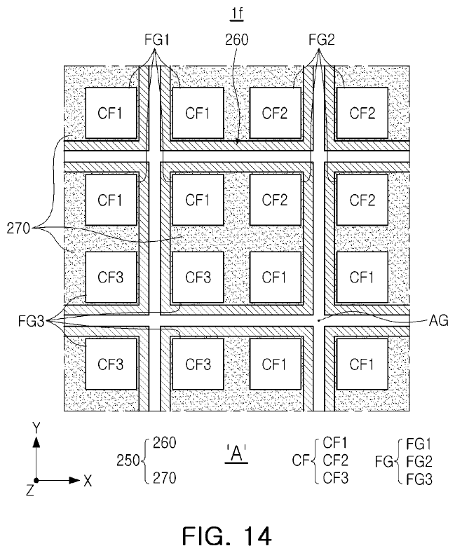

FIGS. 14 to 16 are plan views of an image sensor according to some example embodiments.

Referring to FIG. 14, an image sensor 1f may include a grid structure 250 disposed between color filters CF, the grid structure 250 including a first grid structure 260 and a plurality of second grid structures 270. In some example embodiments, the first grid structure 260 may extend in an X-direction and a Y-direction, between color filters CF included in the same filter group FG. For example, the first grid structure 260 may extend between first color filters CF1 included in a first filter group FG1. The first grid structure 260 may also extend between different filter groups FG. In plan view, color filters CF, disposed in the first grid structure 260, may be included in different filter groups FG. For example, two first color filters CF1, one second color filter CF2, and one third color filter CF3, disposed in the first grid structure 260, may be included in different filter group FG, respectively.

In some example embodiments, each of the plurality of second grid structures 270 may be disposed between different filter groups FG. The plurality of second grid structures 270 may have a cross shape, in plan view. For example, each of the plurality of second grid structures 270 may be disposed in the first grid structure 260. For example, each of the plurality of second grid structures 270 may be disposed between color filters CF included in different filter groups FG.

For example, the second grid structure 270 may be disposed between the first color filter CF1 of the first filter group FG1 and the second color filter CF2 of the second filter group FG2, adjacent thereto. The first color filters CF1 of the first filter group FG1 may be spaced apart from each other by the first grid structure 260.

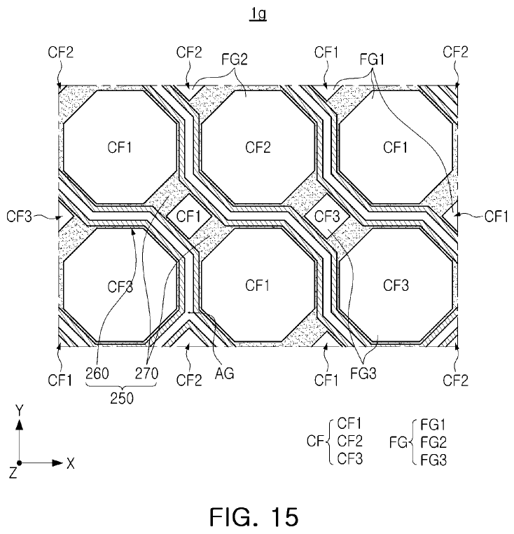

Referring to FIG. 15, an image sensor 1g may include a plurality of color filters CF. In some example embodiments, in plan view, the plurality of color filters CF may have an octagonal shape or a rectangular shape. For example, color filters CF having an octagonal shape may be disposed in the form of a grid in an X-direction and a Y-direction, and color filters CF having a rectangular shape may be disposed between the color filters CF having an octagonal shape.

For example, a first color filter CF1, a second color filter CF2, and a third color filter CF3, having an octagonal shape, may be disposed in the form of a grid in the X-direction and the Y-direction. A first color filter CF1, a second color filter CF2, and a third color filter CF3, having a rectangular shape, may be disposed between the first color filter CF1, the second color filter CF2, and the third color filter CF3, having an octagonal shape. As described above, color filters CF, included in the same filter group FG, may filter the same color.

The image sensor 1g may also include a grid structure 250 disposed between color filters CF, the grid structure 250 including a first grid structure 260 and a second grid structure 270. In some example embodiments, the first grid structure 260 may extend in the X-direction, the Y-direction, and a direction between the X-direction and the Y-direction, between different filter groups FG. As illustrated in FIG. 15, the first grid structure 260 may be disposed between color filters CF included in different filter groups FG.

In some example embodiments, the plurality of second grid structures 270 may be disposed between color filters CF included in the same filter group FG. For example, as illustrated in FIG. 15, an octagonal first color filter CF1 and a rectangular first color filter CF1 may be adjacent to each other, and the second grid structure 270 may be disposed between the octagonal first color filter CF1 and the rectangular first color filter CF1.

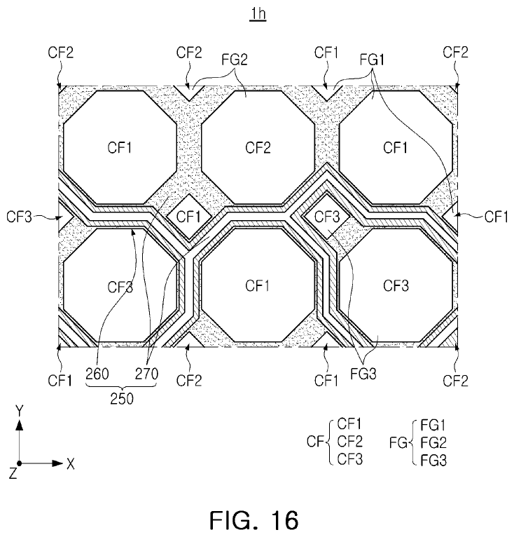

Referring to FIG. 16, an image sensor 1h may include a grid structure 250 disposed between color filters CF, the grid structure 250 including a first grid structure 260 and a second grid structure 270. In some example embodiments, the first grid structure 260 may be disposed to surround one filter group FG, among a plurality of filter groups FG. For example, the first grid structure 260 may be disposed to surround third color filters CF3 included in a third filter group FG3. In some example embodiments, the first grid structure 260 may extend between the third filter groups FG3 to connect adjacent third filter groups FG3 to each other. For example, as illustrated in FIG. 16, the first grid structure 260 may extend along a first color filter CF1, disposed between the third filter groups FG3.

The first grid structure 260 may be disposed to surround a filter group FG including a color filter CF configured to filter a particular color, thereby improving light sensitivity of a desired color and limiting and/or preventing an optical crosstalk phenomenon with adjacent filter groups FG or different types of filter groups FG.

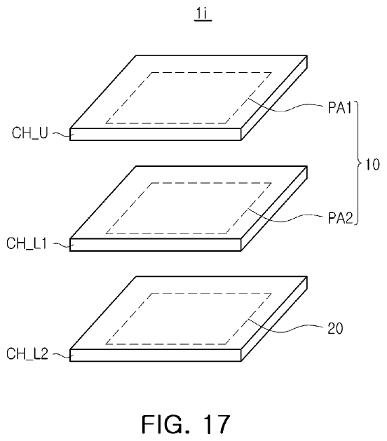

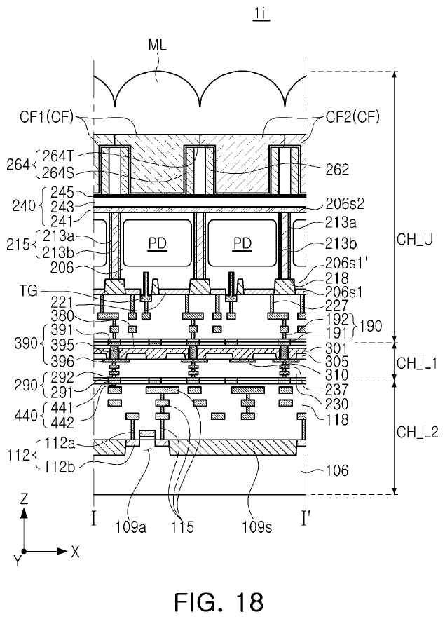

FIG. 17 is a chip configuration diagram of an image sensor according to some example embodiments. FIG. 18 is a cross-sectional view of the image sensor in FIG. 17.

Referring to FIGS. 17 and 18, an image sensor 1i may include a plurality of chips, sequentially stacked. For example, the plurality of chips may include an upper chip CH_U, a first lower chip CH_L1 below the upper chip CH_U, and a second lower chip CH_L2 below the first lower chip CH_L1.

The first lower chip CH_L1 and the upper chip CH_U may include a pixel array 10, and the second lower chip CH_L2 may include a logic circuit 20.

Each of components (devices) of a plurality of pixels (PX in FIG. 1), included in the pixel array 10, may be divided into the first lower chip CH_L1 and the upper chip CH_U. For example, the upper chip CH_U may include a first pixel region PA1, and the first lower chip CH_L1 may include a second pixel region PA2, vertically overlapping the first pixel region PA1. The upper chip CH_U may include a transfer transistor TX, and the first lower chip CH_L1 may include transistors other than the transfer transistor TX.

The upper chip CH_U may include the transfer transistor TX, floating diffusion regions FD, and photodiodes PD, among structures of the substrate 206 described in FIGS. 1 to 6, and a lower portion of the transfer transistor TX may include a first bonding structure 190. The first bonding structure 190 may include a first bonding pad 191 and a first bonding via 192 connected to the first bonding pad 191. The upper chip CH_U may include an insulating structure 240, a grid structure 260, color filters CF, and a microlens ML, and a description thereof may be the same as those in FIGS. 5 and 6.

The first lower chip CH_L1 may include a lower substrate 301 having an upper surface facing the upper chip CH_U, and a lower surface opposing the upper surface, an isolation film 305 defining an active region ACT in the lower substrate 301, circuit devices 310 on the upper surface of the lower substrate 301, an interconnection line region 237 connected to the circuit devices 310, a second upper bonding structure 390 on the upper surface of the lower substrate 301, a second lower bonding structure 290 on the lower surface of the lower substrate 301, a second upper insulating layer 380 on the upper surface of the lower substrate 301, and a second lower insulating layer 230 on the lower surface of the lower substrate 301.

The circuit devices 310 may be transistors other than the transfer transistors TX. The interconnection line region 237 may be disposed between the lower substrate 301 and the second lower chip CH_L2. The interconnection line region 237 may apply an electrical signal to the circuit devices 310. The second lower bonding structure 290 may be a structure for bonding with the second lower chip CH_L2. The second lower bonding structure 290 may include a metal material such as copper (Cu) or the like. The second lower bonding structure 290 may include a second bonding pad 291 and a second bonding via 292 connected to the second bonding pad 291. The second bonding pad 291 of the first lower chip CH_L1 may be in contact with a third bonding pad 441 of the second lower chip CH_L2. The second bonding pad 291 may function as a bonding layer, and may provide an electrical connection path with the second lower chip CH_L2.

The second upper insulating layer 380 may include a bonding insulating layer having a desired (and/or alternatively predetermined) thickness from a lower surface thereof. The bonding insulating layer may be a layer for dielectric-dielectric bonding with a bonding insulating layer of the upper chip CH_U.

The second upper bonding structure 390 may be a structure for bonding with the upper chip CH_U. The second upper bonding structure 390 may include a third bonding pad 391 on the upper surface of the lower substrate 301, a landing structure 396 disposed on the lower surface of the lower substrate 301, and a third bonding via 395 disposed between the third bonding pad 391 and the landing structure 396. The third bonding pad 391 may include a metal material such as copper (Cu) or the like, and the third bonding via 395 may include a metal material such as copper (Cu), tungsten (W), or the like. The third bonding pad 391 may include a metal material the same as that of the third bonding via 395, but the inventive concepts are not limited thereto. The third bonding pad 391 may be in contact with the first bonding pad 191 of the first bonding structure 190 of the upper chip CH_U.

The second lower chip CH_L2 may include a lowermost substrate 106, a lowermost interconnection line structure 115 connected to lowermost circuit devices 112, a third bonding structure 440 on the lowermost interconnection line structure 115, and a logic insulating layer 118 covering the lowermost circuit devices 112 and the lowermost interconnection line structure 115, on the lowermost substrate 106. The third bonding structure 440 may be connected to the lowermost interconnection line structure 115, on the lowermost interconnection line structure 115. The third bonding structure 440 may include a metal material such as copper (Cu) or the like. The third bonding structure 440 may include a third bonding pad 441 and a third bonding via 442 connected to the third bonding pad 441. The third bonding pad 441 of the second lower chip CH_L2 may function as a bonding layer with the first lower chip CH_L1, and may also provide an electrical connection path with the first lower chip CH_L1. The logic insulating layer 118 may cover the lowermost circuit devices 112 and the lowermost interconnection line structure 115, and may cover a portion of the third bonding structure 440.

As described, an image sensor chip including the pixel array 10 may be separated into two chip structures CH_U and CH_L1, and bonding structures 190 and 390 may perform hybrid bonding on the chip structures CH_U and CH_L1 to electrically connect the chip structures CH_U and CH_L1 to each other, thereby implementing the image sensor 1i by hybrid bonding between three chip structures CH_U, CH_L1, and CH_L2.

FIGS. 19A to 19G are cross-sectional views of a method of manufacturing an image sensor according to some example embodiments.

Referring to FIG. 19A, an insulating structure 240 may be formed on a second surface 206s2 of a substrate 206, and a preliminary sacrificial layer 261 may be formed on the insulating structure 240.

The insulating structure 240 may be formed by sequentially stacking an anti-reflection layer 241, a substrate insulating layer 243, and an etch stop layer 245 on the second surface 206s2 of the substrate 206. A preliminary sacrificial layer 261 may be formed thereon to have a first height h1. The preliminary sacrificial layer 261 may include a spin on carbon (SOC) film containing carbon. For example, the preliminary sacrificial layer 261 may be a spin on hard mask (SOH) film. For example, a thick carbon preliminary sacrificial layer 261 may be formed on the insulating structure 240 using a spin coating method to form a flat and easy-to-manufacture film. When a sacrificial layer pattern having an air gap AG shape is formed using a patterning process, pattern accuracy of a fine line width may be achieved. In some example embodiments, when the substrate insulating layer 243 and the preliminary sacrificial layer 261 have high etch selectivity, the etch stop layer 245 may be omitted.

As illustrated in FIG. 19B, the preliminary sacrificial layer 261 may be patterned to form a sacrificial layer pattern 261P. For example, after a mask pattern defining a grid structure 260 is formed, the preliminary sacrificial layer 261 may be etched according to a mask pattern to form the sacrificial layer pattern 261P. The sacrificial layer pattern 261P may be formed limitedly in a position in which an air gap AG of the grid structure 260 is formed, and may be in the form of a grid having a height h1 and a width W1 of the air gap AG. When the sacrificial layer pattern 261P is formed, the mask pattern may be removed to expose side and upper surfaces of the sacrificial layer pattern 261P.

Referring to FIG. 19C, a preliminary spacer layer 262P having a first thickness t1 may be formed on the sacrificial layer pattern 261P. The preliminary spacer layer 262P may be a material having etch selectivity with the preliminary sacrificial layer 261. For example, the preliminary spacer layer 262P may be formed by adjusting a thickness of at least one of silicon oxide, silicon nitride, and silicon carbonitride using atomic layer deposition (ALD). The preliminary spacer layer 262P may be formed to conformally cover an upper surface of the insulating structure 240 and the side and upper surfaces of the sacrificial layer pattern 261P.

As illustrated in FIG. 19D, a spacer layer 262 may be formed by etching back the preliminary spacer layer 262P to remove a horizontal portion. For example, the preliminary spacer layer 262P, stacked on a horizontal portion of a substrate, may be selectively removed, such that the preliminary spacer layer 262P may remain only on the side surface of the sacrificial layer pattern 261P. Accordingly, the upper surface of the sacrificial layer pattern 261P may be exposed.

Referring to FIG. 19E, a capping layer 264 may be formed. The capping layer 264 may be formed to have a second thickness t2 to conformally cover the upper surfaces of the insulating structure 240, the spacer layers 262, and the sacrificial layer pattern 261P. The capping layer 264 may include at least one of silicon oxide, silicon nitride, and silicon carbonitride, and may be formed of a material the same as that of the spacer layer 262, but the inventive concepts are not limited thereto. The capping layer 264 may be formed to have the second thickness t2, less than the first thickness t1, and may be formed to have a significantly small thickness using ALD. Accordingly, only the capping layer 264 having the significantly small second thickness t2 may be stacked on the upper surface of the sacrificial layer pattern 261P.

Referring to FIG. 19F, the sacrificial layer pattern 261P below the capping layer 264 may be removed by performing a plasma process to form an air gap AG.

For example, when a gas including at least one of oxygen, nitrogen, and hydrogen is plasma-treated and injected using the plasma process, radicals passing through the thin capping layer 264 having the second thickness t2 may react with the sacrificial layer pattern 261P. In some example embodiments, radicals, having high energy, may combine with carbon in the sacrificial layer pattern 261P to form carbon dioxide, methane, carbon monoxide, or the like. The carbon monoxide or carbon dioxide formed as described may have high energy in a gaseous state, and thus may pass through the capping layer 264 having the second thickness t2 and externally escape.

For example, when oxygen radicals are injected through an upper surface of the capping layer 264 by performing an oxygen plasma process, the oxygen radicals may combine with carbon in the sacrificial layer pattern 261P to form carbon dioxide or carbon monoxide, and the carbon dioxide or carbon monoxide may be externally discharged. Accordingly, while the oxygen radicals pass through a thin upper region of the capping layer 264 in a state in which the capping layer 264 is formed, the sacrificial layer pattern 261P may be removed to form the air gap AG below the capping layer 264, such that formation of a grid structure 260 may be completed. In some example embodiments, a side surface of the capping layer 264 may be blocked by the spacer layer 262.

In some example embodiments, only the plasma process is described above. Instead, the sacrificial layer pattern 261P may be decomposed and vaporized using thermal decomposition or decomposition using UV to be externally discharged.

Referring to FIG. 19G, color filters CF may be formed in regions partitioned by the grid structure 260. That is, color filters CF having assigned colors may be deposited between the grid structures 260, and a microlens ML may be formed thereon to form the image sensor 1 in FIG. 5.

According to some example embodiments of the inventive concepts, a grid structure may have an air gap, thereby limiting and/or preventing and/or reducing an optical crosstalk phenomenon. Formation of the grid structure may include forming a sacrificial layer which may then be removed through an upper portion of a capping layer using oxygen plasma for example, to form the air gap, thereby ensuring structural stability. Since the sacrificial layer is entirely removed, light sensitivity of the image sensor may be improved. The structural stability of the air gap may be maintained to have a uniform shape and size, thereby reducing and/or minimizing dispersion of optical properties.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While some example embodiments have been shown and described above, it will be apparent to those skilled in the art that modifications and variations could be made without departing from the scope of the inventive concepts as defined by the appended claims.

What is claimed is:

1. An image sensor comprising:
photoelectric conversion devices in a substrate;
a separation structure in the substrate, the separation structure being between the photoelectric conversion devices;
an insulating structure on the substrate and the separation structure;
color filters on the insulating structure; and
a grid structure on the insulating structure, the grid structure being between the color filters,
wherein the grid structure includes
spacer layers having first surfaces opposing each other, the spacer layers defining an air gap between the first surfaces that oppose each other, and
a capping layer covering upper surfaces of the spacer layers and second surfaces of the spacer layers other than the first surfaces, the capping layer defining an upper limit of the air gap,
wherein each of the spacer layers have a first thickness, and the capping layer has a second thickness less than the first thickness.

2. The image sensor of claim 1, wherein the first thickness of each of the spacer layers is 4 to 7 times the second thickness of the capping layer.

3. The image sensor of claim 1, wherein
the first thickness is 150 Å to 350 Å, and
the second thickness is 20 Å to 60 Å.

4. The image sensor of claim 1, wherein the capping layer and the spacer layers include a same material.

5. The image sensor of claim 1, further comprising:
a passivation layer covering the capping layer, the passivation layer having a third thickness different than the first and second thicknesses.

6. The image sensor of claim 1, wherein the spacer layers and the capping layer are configured to seal the air gap in the grid structure.

7. The image sensor of claim 1, wherein only the capping layer having the second thickness defines the upper limit of the air gap.

8. The image sensor of claim 1, wherein an upper surface of the insulating structure defines a lower limit of the air gap.

9. The image sensor of claim 1, wherein the air gap is recessed into the insulating structure.

10. The image sensor of claim 9, wherein
the spacer layers and an upper surface of the insulating structure define a first region of the air gap over the insulating structure, and the insulating structure defines a second region of the air gap in the insulating structure, and
a width of the first region is greater than a width of the second region.

11. An image sensor comprising:
photoelectric conversion devices in a substrate;
color filters on the substrate; and
a grid structure on the substrate, the grid structure being between the color filters,
wherein the grid structure includes
a pair of side surfaces extending vertically from the substrate, the pair of side surfaces facing each other, and
an upper surface connecting upper portions of the pair of side surfaces, the pair of side surfaces and the upper surface defining an air gap below the upper surface, and
a thickness of the upper surface is less than a thickness of each of side surfaces of the pair of side surfaces.

12. The image sensor of claim 11, wherein the thickness of the upper surface of the grid structure is less than or equal to ⅙ of the thickness of each of the side surfaces.

13. The image sensor of claim 11, wherein the thickness of the upper surface of the grid structure is 50 Å or less.

14. The image sensor of claim 11, further comprising:
an insulating structure including an anti-reflection layer on the substrate and the insulating structure further including a substrate insulating layer on the anti-reflection layer,
wherein the grid structure is on the insulating structure.

15. The image sensor of claim 14, wherein the insulating structure further includes an etch stop layer on the substrate insulating layer, and the grid structure is on the etch stop layer.

16. The image sensor of claim 15, wherein the air gap extends through the etch stop layer and into the substrate insulating layer.

17. The image sensor of claim 11, wherein a lower limit of the air gap is at a level higher than an upper surface of the substrate.

18. The image sensor of claim 11, wherein the side surfaces of the grid structure have a multilayer structure including at least two stacked layers, and the upper surface of the grid structure includes at least one layer.

19. The image sensor of claim 11, further comprising a conductive barrier layer in the air gap of the grid structure.

20. An image sensor comprising:
a lower chip including a logic circuit; and
an upper chip on the lower chip and bonded to the lower chip,
wherein the upper chip includes
a plurality of filter groups including a plurality of color filters on a substrate,
a separation structure in the substrate,
an insulating structure on the substrate and the separation structure,
a grid structure on the insulating structure, the grid structure being between the plurality of color filters, and
a microlens on the grid structure,
wherein the grid structure includes a first grid structure and a second grid structure,
the first grid structure includes spacer layers and a capping layer,
the spacer layers have a first thickness and have first surfaces opposing each other, the spacer layers define an air gap between the first surfaces that oppose each other,
the capping layer covers the air gap, upper surfaces of the spacer layers, and second surfaces of the spacer layers other than the first surfaces,
the capping layer has a second thickness less than the first thickness,
each of the plurality of filter groups is surrounded by the first grid structure, and
the second grid structure is between the plurality of color filters in each of the plurality of filter groups.
